(19) United States
(12) Patent Application Publication
(10) Pub. No.: US 2026/0100719 A1
(43) Pub. Date: Apr. 9, 2026

(54) CHARGE BALANCED WIDEBAND TRACK-AND-HOLD BOOSTED BOOTSTRAPPED COMPLEMENTARY INPUT SWITCH

(71) Applicant: Analog Devices, Inc., Wilmington, MA (US)

(72) Inventors: Ralph D. MOORE, Greensboro, NC (US); Franklin M. Murden, Moneta, VA (US)

(21) Appl. No.: 18/906,768

(22) Filed: Oct. 4, 2024

(51) Int. Cl. H03M 1/12; G11C 27/02

(52) U.S. Cl. CPC H03M 1/1245; G11C 27/02

(57) ABSTRACT

In an aspect, a circuit includes a first bootstrap capacitor configured to sample a varying input voltage during a first sample period. In an aspect, the circuit further includes a second bootstrap capacitor configured to sample the varying input voltage during a second sample period. In an aspect, the circuit also includes a switching circuit configured to connect and disconnect the first bootstrap capacitor and the second bootstrap capacitor from the varying input voltage during at least one hold period. In an aspect, the circuit additionally includes an input circuit configured to provide the varying input voltage to the first bootstrap capacitor and the second bootstrap capacitor responsive to a connection configuration of the switching circuit. The input circuit includes three complementary switch pairs. At least two of the three switch pairs are configured to share a common node that is, in turn, configured to receive the varying input voltage.

### TECHNICAL FIELD

Aspects of the present disclosure relate generally to charge storage and, more particularly, to a charge balanced wideband track-and-hold boosted bootstrapped complementary input switch.

### BACKGROUND

A track-and-hold amplifier (THA) captures an analog signal and holds the analog signal constant during some operation (most commonly analog-to-digital conversion). The circuitry involved is demanding, and unexpected properties of commonplace components such as capacitors and printed circuit boards may degrade THA performance. When the track-and-hold amplifier is in the track (or sample) mode, the output follows the input with ideally only a small voltage offset. There do exist sampling configurations where the output during the sample mode does not follow the input accurately (may even return to a reset or zero value), and the output is only accurate during the hold period. These will not be considered here. Strictly speaking, a sample-and-hold with good tracking performance should be referred to as a track-and-hold circuit, but in practice the terms are often used interchangeably.

Analog-to-digital converters (ADCs) are typically made up of two sections. The first section is a sampling circuit which holds a changing input signal constant at the output of the track-and-hold amplifier for a short time while the second section, or quantizing stage, generates the digital result. Most often the track-and-hold amplifier has a gain of 1, but in some applications it can have gains greater or less than 1. When the THA is used with an ADC (either externally or internally), the THA performance is critical to the overall dynamic performance of the combination, and plays a major role in determining the Spurious Free Dynamic Range, Signal to Noise Ratio, etc., of the system.

Regardless of the circuit details or type of THA in question, all such devices have four major components common to all THAs, namely an input buffer amplifier, a switching circuit, an energy storage device (capacitor), and an output buffer.

A basic idea of a simple track-and-hold circuit is now described. An input amplifier stage buffers an input by presenting a controlled impedance to a signal source and providing current gain to charge a hold capacitor. In the track mode, a switch is closed and the voltage on the hold capacitor follows (or tracks) the input signal (with some delay and bandwidth limiting). In the hold mode, the switch is opened, and the hold capacitor retains the voltage present at the time the hold capacitor was disconnected from the input buffer. The output buffer offers a high impedance to the hold capacitor to keep the held voltage from discharging prematurely. The switching circuit and its driver form the mechanism by which the THA is alternately switched between track-and-hold functionality.

While advances in track-and-hold methods have been made, linearity and turn-on speed for both sample (track) and hold cases need to be improved.

### SUMMARY

The following presents a simplified summary of one or more aspects to provide a basic understanding of such aspects. This summary is not an extensive overview of all contemplated aspects and is intended to neither identify key or critical elements of all aspects nor delineate the scope of any or all aspects. Its sole purpose is to present some concepts of one or more aspects in a simplified form as a prelude to the more detailed description that is presented later.

According to aspects of the present disclosure, a circuit is provided. In an aspect, the circuit includes a first bootstrap capacitor configured to apply a pre-set direct current (D.C.) boosted voltage across the bootstrapped input switch during a sample period. In an aspect, the circuit further includes a second bootstrap capacitor configured to apply a pre-set D.C. boosted voltage across the bootstrapped input switch during the sample period. In an aspect, the circuit also includes a switching circuit configured to connect and disconnect the first bootstrap capacitor and the second bootstrap capacitor from the varying input voltage during a hold period. In an aspect, the circuit additionally includes an input circuit configured to provide the varying input voltage to the first bootstrap capacitor and the second bootstrap capacitor responsive to a connection configuration of the switching circuit. The input circuit includes three complementary switch pairs. The three complementary switch pairs are configured to share a common node that is, in turn, configured to receive the varying input voltage.

According to other aspects of the present disclosure, a method is provided. In an aspect, the method includes configuring a first bootstrap capacitor to apply a pre-set direct current (D.C.) boosted voltage across the bootstrapped input switch during a sample period. In an aspect, the method further includes configuring a second bootstrap capacitor to apply a pre-set D.C. boosted voltage across the bootstrapped input switch during the sample period. In an aspect, the method also includes configuring a switching circuit to connect and disconnect the first bootstrap capacitor and the second bootstrap capacitor from the varying input voltage during a hold period. In an aspect, the method additionally includes configuring an input circuit to provide the varying input voltage to the first bootstrap capacitor and the second bootstrap capacitor responsive to a connection configuration of the switching circuit, the input circuit comprising three complementary switch pairs, the three complementary switch pairs being configured to share a common node that is, in turn, configured to receive the varying input voltage.

To the accomplishment of the foregoing and related ends, the one or more aspects comprise the features hereinafter fully described and particularly pointed out in the claims. The following description and the annexed drawings set forth in detail certain illustrative features of the one or more aspects. These features are indicative, however, of but a few of the various ways in which the principles of various aspects may be employed, and this description is intended to include all such aspects and their equivalents.

### BRIEF DESCRIPTION OF THE DRAWINGS

The disclosed aspects will hereinafter be described in conjunction with the appended drawings, provided to illustrate and not to limit the disclosed aspects, wherein like designations denote like elements, and in which.

FIG. 1 is a schematic diagram of an example track-and-hold (TH) boosted bootstrapped input switches circuit (BISC), in accordance with an exemplary aspect.

FIG. 2 is a schematic diagram of an example track-and-hold (TH) boosted bootstrapped input switches circuit (BISC), in accordance with an exemplary aspect.

FIG. 3 is a schematic diagram of an example track-and-hold (TH) boosted bootstrapped input switches circuit (BISC), in accordance with an exemplary aspect.

FIG. 4 is a schematic diagram of an example track-and-hold (TH) boosted bootstrapped input switches circuit (BISC), in accordance with an exemplary aspect.

FIG. 5 is a flow chart of an example method for forming a track-and-hold (TH) boosted bootstrapped input switches circuit (BISC), in accordance with an exemplary aspect.

FIGS. 6-7 are flow charts of an example method corresponding to TH BISC of FIG. 1 and method of FIG. 5, in accordance with an exemplary aspect.

FIGS. 8-9 are flow charts of an example method corresponding to TH BISC of FIG. 2 and method of FIG. 5, in accordance with an exemplary aspect.

FIG. 10 is a flow chart of an example method corresponding to TH BISC of FIG. 3 and method of FIG. 5, in accordance with an exemplary aspect.

### DETAILED DESCRIPTION

The present disclosure is directed to track-and-hold (TH) boosted bootstrapped input switches circuits (BISCs)and methods for forming track-and-hold (TH) boosted bootstrapped input switches circuits (BISCs)with improved linearity and faster turn on speed for both sample and hold cases.

Aspects of the present disclosure leverage elements such as the switch and capacitor. Aspects of the present disclosure are inherently faster than prior art approaches by bypassing biasing and buffer impedance.

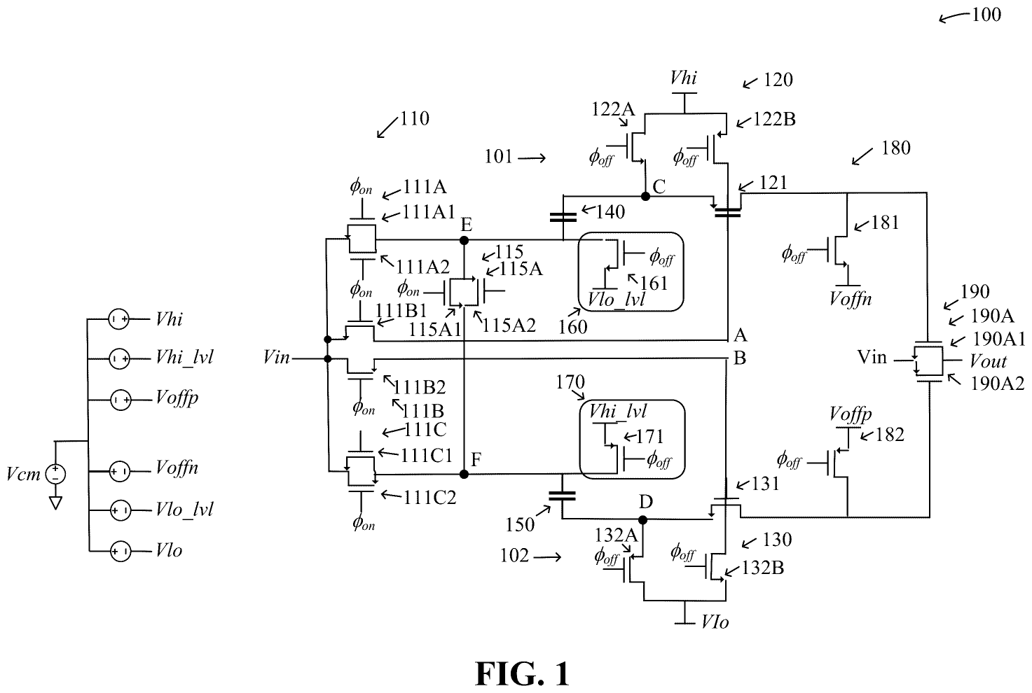

In an aspect, a differential bootstrap generator is used. For example, all of the elements in FIGS. 1-4 may be considered to form respective differential bootstrap generators.

In an aspect, a SWC (switched capacitor circuit) track-and-hold (TH) with a differential bootstrapped input switch and structures is provided.

In an aspect, a SWC circuit is made “benign” to the buffer as much as possible. As used herein, “benign”refers to having little to no detrimental effect.

In an aspect, an ideal load is a capacitor with some series switch resistance. In an aspect, the goal is one to reduce the problem to simply target the buffer load over time. To achieve this goal, switch non-idealities are suppressed as much as possible.

In an aspect, current resulting from switch parasitics are confined to the gate node. The basic complementary switch provides a good foundation. However, in an aspect, cancellation techniques are employed that extend into the generation of clocks to realize full potential. The speed increase stems from leveraging charge distribution, thereby minimizing bypassing the effects of reference and buffer resistance. Hence, in an aspect, currents are confined to short local loops in clock generation, particularly bootstrapping.

Bootstrapping refers to pulling up the operating point of a switching transistor above the power supply rail voltage. Typically, in an “off” state, the gate of the bootstrapped switch is connected to a fixed voltage, such as ground, and, in an “on” state, a constant voltage is applied across the gate-to-source terminals. That is, the gate voltage can track the input voltage shifted by some voltage, keeping the gate-to-source voltage constant regardless of the input signal. Benefits of the constant gate-to-source voltage are that the switch resistance is independent of input signal, and much of the switch parasitic capacitance, such as the Cgs and Cgd, do not load the input. Boosted Bootstrapped switches 190, 290, 390, and 490 are described with respect to FIGS. 1, 2, 3, and 4, respectively. The benefits of complementary boosted bootstrapping include, but are not limited to the even-order harmonics being lower to due to the use of the complementary CMOS switches The complementary and unique configuration of the turn-on and turn-off circuits described herein first order eliminate any switching charge kicking back to Vin.

In an aspect, the current resulting from switch parasitics being confined to the gate node and the confinements of current to short local loops lead to significant design freedom in the track-and-hold (TH) or any variant with gain, including open-loop and closed-loop variants. The input switches, the samples switches, and the hold switches all may leverage the techniques described herein which can apply to any variation of the switch, e.g., sample switch to bias level and/or full differential switch.

Aspects of the present disclosure use a complementary transistor pair 190, 290, 390, 490 which has a common input and interconnections such that both are either on or off at any given time.

Aspects of the present disclosure may use a variable gain amplifier. Most data acquisition systems with wide dynamic range need a method of adjusting the input signal level to the analog-to-digital-converter (ADC). Typical ADC full scale input voltage ranges typically lie between 0.5 V and 2 V. To achieve the rated precision of the converter, the maximum input signal should be fairly near its full scale voltage. Transducers, however, have a very wide range of output voltages. High gain is needed for a small sensor voltage, but with a large output, a high gain will cause the amplifier or ADC to saturate. Thus, some type of predictably controllable gain device is needed. Amplifiers with programmable gain have a variety of applications. Such a device has a gain that is controlled by a dc voltage or, more commonly, a digital input. This device is known as a variable gain amplifier (VGA), or programmable gain amplifier (PGA).

### Track-and-Hold (TH) Boosted Bootstrapped Input Switches Circuit (BISC) 100

Referring to FIG. 1, an example track and hold (TH) boosted bootstrapped input switches circuit (BISC) TH BISC 100 is shown, in accordance with an exemplary aspect. It is to be appreciated that TH BISC 100, as well as the following described TH BISC 200, TH BISC 300, and TB BISC 400 may all include a hold capacitor having a first end coupled to Vout and a second end coupled to a sample switch, where the sample switch is coupled to ground at another end.

TH BISC 100 is advantageous over TH BISC 200, 300, 400 in that TH BISC 100 can support larger boost voltages, i.e., the amount of voltage that the gate of switch 190 is boosted above Vin. This is achieved by controlling Vlo_lvl to be less than Vhi_lvl.

SH-SWC 100 is advantageous in that there is control over a very low level (Vlo_lvl) and a very high level (Vhi_lvl). Thus, if you make Vlo_lvl to be less than Vhi_lvl, you can boost to a greater voltage or bootstrap to a greater voltage and that is potentially desirable.

The downside of SH-SWC 100 is that these other voltages Vlo_lvl and Vhi_lvl have to be generated. If you do not have those voltages or you do not want to generate those voltages.

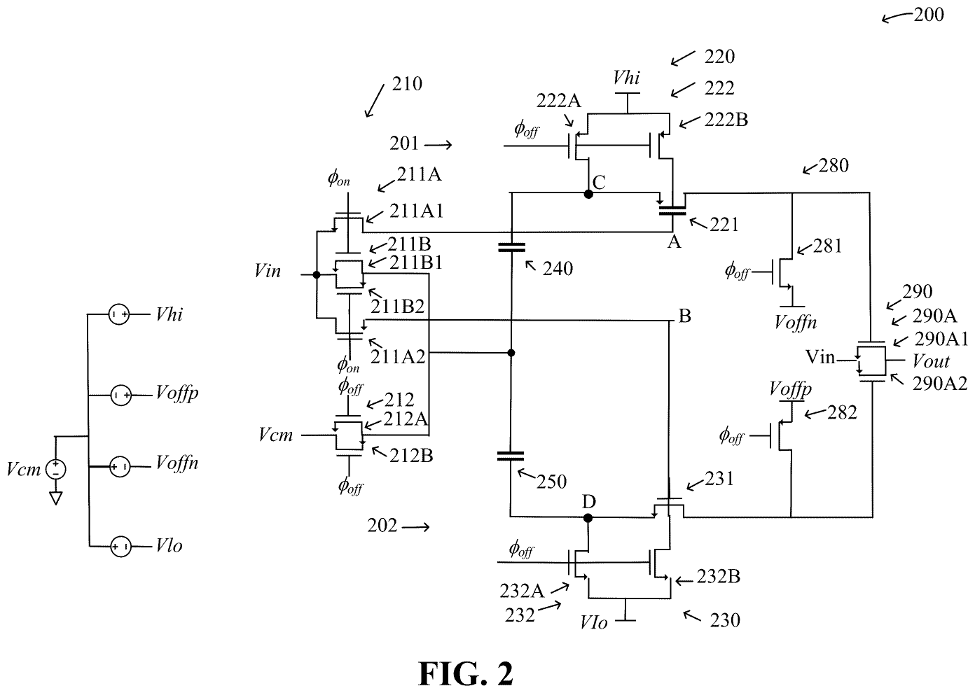

In contrast, the TH BISC 200 of FIG. 2 described hereinbelow could be used where the two capacitors 240 and 250 are connected together and to a VCM (common mode voltage) or a fixed DC level.

TH BISC 100 is another circuit, in addition to the others mentioned hereinafter (200, 300, 400), that can boost beyond the traditional rail in order to maximize the input switch (M1, M2) |Vgs|to the limit of the process. Splitting and separating the bootstrap capacitors 140, 150 allows a level shift operation to take place. Rather than expanding Vhi and Vlo, the expansion may be implemented on the middle plate of the capacitors 140, 150 with vhi_lvl and Vlo_lvl.

In an aspect, transistors 122A, 132A change from negative metal oxide semiconductor (NMOS) in the case of transistor 122A to positive metal oxide semiconductor (PMOS) in the case of transistor 132A. In an aspect, bias for the middle node is no longer Vcm. Instead, bias for the middle node is vhi_lvl and Vlo_lvl.

Regarding an example involving a 1.8 V supply with a Vcm of 0.9 V allows Vhi to be <<1.8 V and Vlo>>0 V and all bias voltages are easily derived from 1 V or 1.8 V supplies. For example, in any aspect, consider Vhi_lvl=1.4 V and Vlo_lvl=0.4 V. Entering the track phase, complementary switch pair 115A simultaneously closes level shifting input switch gates by additional |Vhi_lvl−0.9 V|*β for β=C/(C+Cparasitic).

In an aspect, stress on the transistors 121, 131 drain-source in the hold phase is reduced with Vhi and Vlo. Turn off switches 181, 182 may still be used.

The TH BISC 100 includes a first branch 101 for generating a voltage boosted by some positive voltage above an analog input voltage V_{IN}. The TH BISC 100 includes a second branch 102 for generating a voltage boosted by some negative voltage below an analog input voltage Vin.

The TH BISC 100 includes an input circuit 110, a boost turn-on circuit 115, a first switch circuit 120, a second switch circuit 130, a first storage element (hereinafter “bootstrap capacitor”) 140, a second storage element hereinafter “bootstrap capacitor”) 150, a first level circuit 160, a second level circuit 170, a boost turn-off circuit 180, and an output circuit 190.

The input circuit 110 is configured to receive analog input voltage V_{IN} and either isolate Vin from the reset of TH BISC 100, or connect Vin to nodes A, B, E, and F.

When input circuit 110 is on (all switches closed) 100 is in track (sample) mode and Vin is tied to nodes A, B, E, and F. Boost turn-on circuit 115 is on (all switches closed). Circuits 120, 130, 160, 170, and 180 are off (all switches open). Node C is tied to the gate of 190A1 and Node E is tied to Vin. Node D is tied to the gate of 190A2 and Node F is tied to Vin. Vboost has been applied across 140 and 150 during hold mode and nodes C and D track Vin with a level shift of +/−Vboost respectively. Output circuit 190 is on (all switches closed).

When input circuit 110 is off (all switches open) 100 is in hold mode and TH BISC 100 is isolated from Vin. Boost turn-on circuit 115 is off (all switches open). Circuits 120, 130, 160, 170, and 180 are on (all switches closed). Node C is tied to Vhi, Node E is tied to Vlo_lvl, Node F is tied to Vhi_lvl, and Node D is tied to Vlo. Vhi-Vlo_lvl (Vboost) is applied across 140 and Vhi_lvl-Vlo (Vboost) is applied across 150. Output circuit 190 is off (all switches open). Bootstrap capacitors 140 and 150 do not have to have the same Vboost voltage.

First branch 101 includes elements of input circuit 110, boost turn-on circuit 115, bootstrap capacitor 140, first level circuit 160, boost turn-off circuit 180, and output circuit 190. First branch 101 includes nodes E, C, and A described further hereinbelow. Second branch 102 includes elements of input circuit 110, boost turn-on circuit 115, bootstrap capacitor 150, second level circuit 170, boost turn-off circuit 180, and output circuit 190. Second branch 102 includes nodes F, D, and B described further hereinbelow.

### Input Circuit 110

The input circuit 110 includes three complementary switch pairs configured to receive analog input voltage V_{IN}, namely a complementary switch pair 111A, a complementary switch pair 111B, and a complementary switch pair 111C. In an aspect as shown, complementary switch pair 111B is disposed between complementary switch pair 111A and complementary switch pair 111C. Complementary switch pair 111A includes a transistor 111A1 and a transistor 111A2. Complementary switch pair 111B includes a transistor 111B1 and a transistor 111B2. Complementary switch pair 111C includes a transistor 111C1 and a transistor 111C2.

Gates of transistor 111A1, transistor 111A2, transistor 111B1, transistor 111B2, transistor 111C1, and transistor 111C2 are commonly connected and configured to receive a control signal ∅ₒₙ to turn the transistors 111A1, 111A2, 111B1, 111B2, 111C1, and 111C2 all on or all off.

A source of transistor 111B1 is connected to a node A. A drain of transistor 111B2 is connected to a node B.

### First Switch Circuit 120 and Second Switch Circuit 130

Node A, in addition to being connected to the source of transistor 111B1, is further connected to a source of transistor 122B and a gate of transistor 121. Node B, in addition to being connected to the drain of transistor 111B2, is further connected to a source of transistor 132B and a gate of transistor 131.

First switch circuit 120 includes a transistor 121 and complementary switch pair 122. Complementary switch pair 122 includes a transistor 122A and a transistor 122B. A source of transistor 122A and a drain of transistor 122B are connected to a voltage Vₕᵢ. Gates of transistor 122A and transistor 122B are connected to a control signal ∅_{off}. A drain of transistor 122A, a drain of transistor 121, and a first end of capacitor 140 form node C.

Second switch circuit 130 includes a transistor 131 and complementary switch pair 132. Complementary switch pair 132 includes a transistor 132A and a transistor 132B. A source of transistor 132A and a drain of transistor 132B are connected to a voltage Vₗₒ. Gates of transistor 132A and transistor 132B are connected to a control signal ∅_{off}. A drain of transistor 132A, a drain of transistor 131, and a first end of capacitor 150 form node D.

### Bootstrap Capacitor 140 and Bootstrap Capacitor 150

Bootstrap capacitors 140 and 150 are configured to store a pre-set D.C. boosted voltage (Vboost).

### Boost Turn-on Circuit 115

Boost turn-on circuit 115 includes a complementary switch pair 115A having a transistor 115A1 and a transistor 115A2. Gates of transistor 115A1 and transistor 115A2 are connected to control signal ∅ₒₙ. A source of transistor 161 of first level circuit 160 described in further detail hereinbelow is connected to a second end of capacitor 140, a source of transistor 111A1, a drain of transistor 111A2, a source of a transistor 115A1, and a drain of a transistor 115A2 to form node E. A source of transistor 171 of second level circuit 170 described in further detail hereinbelow is connected to a second end of capacitor 150, a source of transistor 111C1, a drain of transistor 111C2, a drain of a transistor 115A1, and a source of a transistor 115A2 to form node F.

### First Level Circuit 160 and Second Level Circuit 170

First level circuit 160 includes transistor 161. Second level circuit 170 includes transistor 171 Gates of transistors 161 and 171 are connected to control signal ∅_{off}. A drain of transistor 161 is connected to a voltage Vlo_lvl. A drain of transistor 171 is connected to a voltage Vhi_lvl.

### Boost Turn-off Circuit 180

Boost turn-off circuit 180 includes a transistor 181 and a transistor 182. Transistor 181 includes a drain connected to a voltage V_{offn}, a source connected to a source of transistor 121 and a gate of a transistor 190A1 of a complementary switch pair 190A of output circuit 190 described in further detail hereinbelow. Transistor 182 includes a drain connected to a voltage V_{offp}, a source connected to a source of transistor 131 and a gate of a transistor 190A2 of a complementary switch pair 190A of output circuit 190 described in further detail hereinbelow.

### Output Circuit 190

Output circuit 190 includes a complementary switch pair 190A having transistor 190A1 and transistor 190A2. Drains of transistor 190A1 and transistor 190A2 are connected to input voltage V_{IN}. Sources of transistor 190A1 and transistor 190A2 are connected to an output voltage V_{OUT}.

The on resistances of transistor 190A1 and transistor 190A2 are boosted and bootstrapped to be of constant resistance and look like a resistor.

Consider the following values in the TH BISC 100. When the gate of transistor 190A1 is a +0.9V and the gate of transistor 190A2 is a −0.9V, transistor 181 is turned off and transistor 121 is turned on, putting a voltage of 0.9V across capacitor 140.

### Circuit Voltages

TH BISC 100 includes various voltage sources including voltage sources Vhi, Vhi_lvl, Voffp, Voffn, Vlo_lvl, and Vlo. ****I have reviewed to here.******

### Track-and-Hold (TH) Boosted Bootstrapped Input Switches Circuit (BISC) 200

Referring to FIG. 2, an example track and hold (TH) boosted input switches circuit (BISC) 200 is shown, in accordance with an exemplary aspect.

TH BISC 200 of FIG. 2 differs from TH BISC 100 of FIG. 1 in reconfiguring the transistors of the input circuit 210 of TH BISC 200 relative to the transistors of the input circuit 110 of TH BISC 100, as well as the omission of first level circuit 160 and second level circuit 170 in TH BISC 200. The reconfiguring of the transistors of the input circuit 110 of FIG. 1 to obtain input circuit 220 of FIG. 2 provides less boost, but TH BISC 200 is a simpler circuit with less voltages to generate than TH BISC 100.

In an aspect, bias voltages are referenced to voltage Vcm and are designed to avoid over voltage at the switch terminals. In an aspect, transistors 211B and 212 are complementary metal oxide semiconductor (CMOS) to minimize clock charge injection back to the buffer and internal to bootstrap. In an aspect, transistors 221 and 231 are bootstrapped to an analog input voltage V_{IN}.

In an aspect, TH BISC 200 will provide better linearity and faster settling entering/exiting tracking phase due to more benign switching transients. Due to charge distribution and a proper choice for Voff, then there is no overvoltage issue with transistors 221, 231, 281, 282. Using an example of a buffer on 1.8 V domain with Vcm=900 mV, it is clear for this configuration that the absolute maximum input switch |Vgs| is <900 mV. In practice, this will be a direction function of bootstrap capacitance value and parasitic capacitance. It is reasonable to obtain ˜700-800 mv.

The TH BISC 200 includes a first branch 201 for generating a voltage boosted by some positive voltage above an analog input voltage V_{IN}. The TH BISC 200 includes a second branch 202 for generating a voltage boosted by some negative voltage below an analog input voltage Vin.

The TH BISC 200 includes an input circuit 210, a first switch circuit 220, a second switch circuit 230, a first storage element (hereinafter “capacitor”) 240, a second storage element hereinafter “capacitor”) 250, a boost turn-off circuit 280, and an output circuit 290.

Input circuit 210 provides the switching to charge the bootstrap capacitors 240 and 250 during hold mode and connect bootstrap capacitors 240 and 250 to Vin during track mode. In the track mode, the voltage on the bootstrap capacitors 240 and 250 follow (or track) the input signal V_{IN} and provide a boosted signal to the gates of 221 and 231 respectively. In the hold mode, the bootstrap capacitors 240 and 250 are disconnected from Vin and are serially connected and charged between Vhi and Vlo through 222A and 232A respectively. The output circuit 290 offers a high impedance to the bootstrap capacitors 240 and 250 to keep the held voltages stored therein from discharging prematurely.

First branch 201 includes elements of input circuit 210, capacitor 240, boost turn-off circuit 280, and output circuit 290. First branch 201 includes nodes C and A described further hereinbelow. Second branch 202 includes elements of input circuit 210, capacitor 240, boost turn-off circuit 280, and output circuit 290. Second branch 201 includes nodes D and B described further hereinbelow.

### Input Circuit 210

The input circuit 210 includes two complementary switch pairs configured to receive analog input voltage V_{IN}, namely a complementary switch pair 211A and a complementary switch pair 211B. In an aspect as shown, complementary switch pair 211B is disposed between a transistor 211A1 and a transistor 211A2 of complementary switch pair 211A. Complementary switch pair 211A includes transistor 211A1 and transistor 211A2. Complementary switch pair 211B includes a transistor 211B1 and a transistor 211B2.

The input circuit 210 further includes a third complementary switch pair 211C configured to receive a common mode voltage Vcm. Complementary switch pair 211C includes a transistor 211C1 and a transistor 211C2.

Gates of transistor 211A1, transistor 211A2, transistor 211B1, and transistor 211B2, are commonly connected and configured to receive a control signal ∅ₒₙ to turn the transistors 211A1, 211A2, 211B1, and 211B2 all on or all off. Gates of transistor 211C1 and transistor 211C2 are commonly connected and configured to receive a control signal ∅_{off} to turn the transistors 2111C1 and 211C2 all on or all off. A source of transistor 211A1 is connected to a node A. A drain of transistor 211A2 is connected to a node B.

### First Switch Circuit 220 and Second Switch Circuit 230

Node A, in addition to being connected to the source of transistor 211A1, is further connected to a gate of transistor 221. Node B, in addition to being connected to the drain of transistor 211A2, is further connected to a gate of transistor 231.

First switch circuit 220 includes a transistor 221 and complementary switch pair 222. Complementary switch pair 222 includes a transistor 222A and a transistor 222B. A drain of transistor 222A and a drain of transistor 222B are connected to a voltage Vₕᵢ. Gates of transistor 222A and transistor 222B are connected to a control signal ∅_{off}. A source of transistor 222A, a drain of transistor 221, and a first end of capacitor 240 form node C.

Second switch circuit 230 includes a transistor 231 and complementary switch pair 232. Complementary switch pair 232 includes a transistor 232A and a transistor 232B. A drain of transistor 232A and a drain of transistor 232B are connected to a voltage Vₗₒ. Gates of transistor 232A and transistor 232B are connected to a control signal ∅_{off}. A source of transistor 232A, a drain of transistor 231, and a first end of capacitor 250 form node D.

### Capacitor 240 and Capacitor 250

Capacitors 240 and 250 are configured to store a pre-set D.C. boosted voltage (Vboost).

### Boost Turn-off Circuit 280

Boost turn-off circuit 289 includes a transistor 281 and a transistor 282. Transistor 281 includes a drain connected to a voltage V_{offn}, a source connected to a source of transistor 221 and a gate of a transistor 290A1 of a complementary switch pair 290A of output circuit 290 described in further detail hereinbelow. Transistor 282 includes a drain connected to a voltage VV_{offp}, a source connected to a source of transistor 231 and a gate of a transistor 290A2 of a complementary switch pair 290A of output circuit 290 described in further detail hereinbelow.

### Output Circuit 290

Output circuit 290 includes a complementary switch pair 290A having transistor 290A1 and transistor 290A2. Drains of transistor 290A1 and transistor 290A2 are connected to input voltage V_{IN}. Sources of transistor 290A1 and transistor 290A2 are connected to an output voltage V_{OUT}.

The on resistances of transistor 290A1 and transistor 290A2 are boosted and bootstrapped to be of constant resistance and look like a resistor.

Consider the following values in the TH BISC 200. When the gate of transistor 290A1 is 0.9V above Vcm and the gate of transistor 290A2 is 0.9V below Vcm, transistors 281 and 282 are turned off and transistors 221 and 231 are turned on, putting a voltage of 0.9V across capacitors 240 and 250.

### Circuit Voltages

TH BISC 200 includes various voltage sources including voltage sources Vhi, Vhi_lvl, Voffp, Voffn, Vlo_lvl, and Vlo.

### Track and Hold (TH) Boosted Input Switches Circuit (BISC) 300

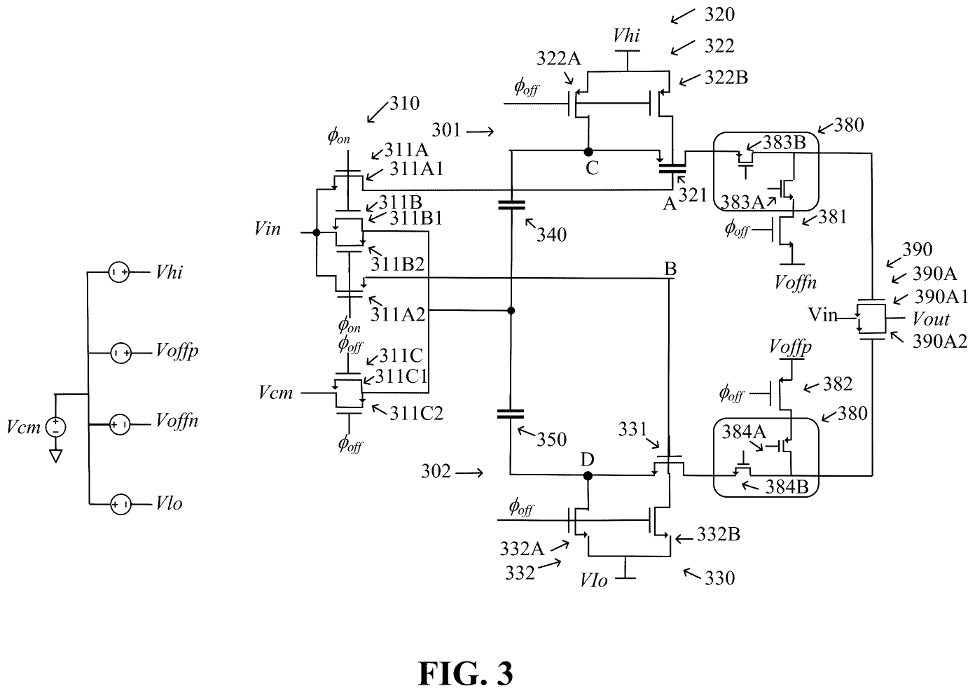

Referring to FIG. 3, an example track and hold (TH) boosted bootstrapped input switches circuit (BISC) 300 is shown, in accordance with an exemplary aspect.

TH BISC 300 of FIG. 3 differs from TH BISC 200 of FIG. 2 in including a protection circuit 380 that, in turn, includes four additional transistors 383A, 383B, 384A, 384B. that function as a protection circuit A reason to add the protection circuit can depend on the corresponding involved process technology, where the supply voltages for newer processes get smaller and smaller and the voltages that any particular transistor can handle across also get smaller and smaller. Regarding the drain, gate and source, the voltage that can be across any two of those terminals gets smaller as you go to newer processes. So when we utilize 0.18 microns, we have 1.8 volts. Now when we utilize 16 nanometer, we have 1.0 volts, and for five nanometer, we have 0.9 volts, and it just keeps shrinking and shrinking.

The voltage that is intended to put into SH_SWC 300 might not be shrinking, but the transistors cannot handle much voltage and so the way you get around that is by stacking devices in series. Thus for example, transistor 383A can be considered a protection device that allows the node at the drain of transistor 383A to go higher than it could otherwise go without damage, for example, without the protection device because you would then damage transistor 381 for example, which is connected to Voffn.

Thus, in the track phase for example, where the signal could be 2-3× above the intended full-scale, the gates of transistors 390A1 and 390A2 may exceed the breakdown voltages of 321, 381, 331, and 382, Thus, by adding the overdrive protection circuitry 380, we allow for a bigger voltage excursion at the gates of transistors 390A1 and 390A2 without any damage to transistors 321, 381, 331, and 382. FIG. 3 would allow Voffn to be a lower voltage and Voffp to be a higher voltage because it is the difference across two terminals that causes trouble in terms of overvoltage. Thus, we could either go higher on the gate or lower on Voffn, both of these action could cause damage, so we add protection devices in protection circuit 380.

In an aspect, it is possible to push the input switch |Vgs|=1 V by Vhi>1.8 V and Vlo<0 while keeping Vcm=0.9 V. The tradeoff is that over-voltage protection devices (such as transistors 383A, 383B, 384A, 384B should be used. Signal full scale will dictate the precise limitations, however as an alternative, and in lieu of using 380, thick oxide devices could be used for 321, 381, 331, and 382 which have a higher breakdown voltage. This would allow for greater signal swing but at the expense of slower turn-on, turn-off, and a potential decrease in bandwidth. The TH BISC 300 includes a first branch 301 for generating a voltage boosted by some positive voltage above an analog input voltage V_{IN}. The TH BISC 300 includes a second branch 302 for generating a voltage boosted by some negative voltage below an analog input voltage Vin.

The TH BISC 300 includes an input circuit 310, a first switch circuit 320, a second switch circuit 330, a first storage element (hereinafter “bootstrap capacitor”) 340, a second storage element hereinafter “bootstrap capacitor”) 350, a boost turn-off circuit 380, and an output circuit 390.

Input circuit 310 buffers input voltage V_{IN} by presenting a high impedance to a signal source and providing current gain to charge bootstrap capacitors 340 and 350. In the track mode, the voltage on the bootstrap capacitors 340 and 350 follow (or track) the input signal V_{IN}. In the hold mode, the bootstrap capacitors 340 and 350 retain the voltage present at the time the bootstrap capacitors 340 and 350 were disconnected from the input circuit 310. The output circuit 390 offers a high impedance to the bootstrap capacitors 340 and 350 to keep the held voltages stored therein from discharging prematurely.

First branch 301 includes elements of input circuit 310, bootstrap capacitor 340, boost turn-off circuit 380, and output circuit 390. First branch 301 includes nodes C and A described further hereinbelow. Second branch 302 includes elements of input circuit 310, bootstrap capacitor 350, boost turn-off circuit 380, and output circuit 390. Second branch 302 includes nodes D and B described further hereinbelow.

### Input Circuit 310

The input circuit 310 includes two complementary switch pairs configured to receive analog input voltage V_{IN}, namely a complementary switch pair 311A and a complementary switch pair 311B. In an aspect as shown, complementary switch pair 311B is disposed between a transistor 311A1 and a transistor 311A2 of complementary switch pair 311A. Complementary switch pair 311A includes transistor 311A1 and transistor 311A2. Complementary switch pair 311B includes a transistor 311B1 and a transistor 311B2.

The input circuit 310 further includes a third complementary switch pair 311C configured to receive a common mode voltage Vcm. Complementary switch pair 311C includes a transistor 311C1 and a transistor 311C2.

Gates of transistor 311A1, transistor 311A2, transistor 311B1, and transistor 311B2, are commonly connected and configured to receive a control signal ∅ₒₙ to turn the transistors 311A1, 311A2, 311B1, and 311B2 all on or all off. Gates of transistor 311C1 and transistor 311C2 are commonly connected and configured to receive a voltage V_{cm} to turn the transistors 3111C1 and 311C2 all on or all off. A source of transistor 311A1 is connected to a node A. A drain of transistor 311A2 is connected to a node B.

### First Switch Circuit 320 and Second Switch Circuit 330

Node A, in addition to being connected to the source of transistor 311A1, is further connected to a gate of transistor 321. Node B, in addition to being connected to the drain of transistor 311A2, is further connected to a gate of transistor 331.

First switch circuit 320 includes a transistor 321 and complementary switch pair 322. Complementary switch pair 322 includes a transistor 322A and a transistor 322B. A drain of transistor 322A and a drain of transistor 322B are connected to a voltage Vₕᵢ. Gates of transistor 322A and transistor 322B are connected to a control signal ∅_{off}. A source of transistor 322A, a drain of transistor 321, and a first end of bootstrap capacitor 340 form node C.

Second switch circuit 330 includes a transistor 331 and complementary switch pair 332. Complementary switch pair 332 includes a transistor 332A and a transistor 332B. A drain of transistor 332A and a drain of transistor 332B are connected to a voltage Vₗₒ. Gates of transistor 332A and transistor 332B are connected to a control signal ∅_{off}. A source of transistor 332A, a drain of transistor 331, and a first end of bootstrap capacitor 350 form node D.

### Bootstrap Capacitor 340 and Bootstrap Capacitor 350

Bootstrap capacitors 340 and 350 are configured to store a pre-set D.C. boosted voltage (Vboost).

### Boost Turn-off Circuit 380

Boost turn-off circuit 380 includes a transistor 381 and a transistor 382.

Transistor 381 includes a drain connected to a voltage V_{offn}, a source connected to a drain of a transistor 383A, and a gate connected to a control signal ∅_{off}. A source of transistor 383A is connected to a source of a transistor 383B, and a gate of a transistor 390A1 of a complementary switch pair 390A of output circuit 390 described in further detail hereinbelow. A drain of transistor 383B is connected to a source of transistor 321.

Transistor 382 includes a drain connected to a voltage V_{offn}, a source connected to a drain of a transistor 384A, and a gate connected to a control signal ∅_{off}. A source of transistor 384A is connected to a source of a transistor 384B, and a gate of a transistor 290A1 of a complementary switch pair 390A of output circuit 390 described in further detail hereinbelow. A drain of transistor 384B is connected to a source of transistor 331.

### Output Circuit 390

Output circuit 390 includes a complementary switch pair 390A having transistor 390A1 and transistor 390A2. Drains of transistor 390A1 and transistor 390A2 are connected to input voltage V_{IN}. Sources of transistor 390A1 and transistor 390A2 are connected to an output voltage V_{OUT}.

The on resistances of transistor 390A1 and transistor 390A2 are boosted and bootstrapped to be of constant resistance and look like a resistor.

### Circuit Voltages

TH BISC 300 includes various voltage sources including voltage sources Vhi, Voffp, Voffn, and Vlo.

### Track and Hold (TH) Boosted Bootstrapped Input Switches Circuit (BISC) 400

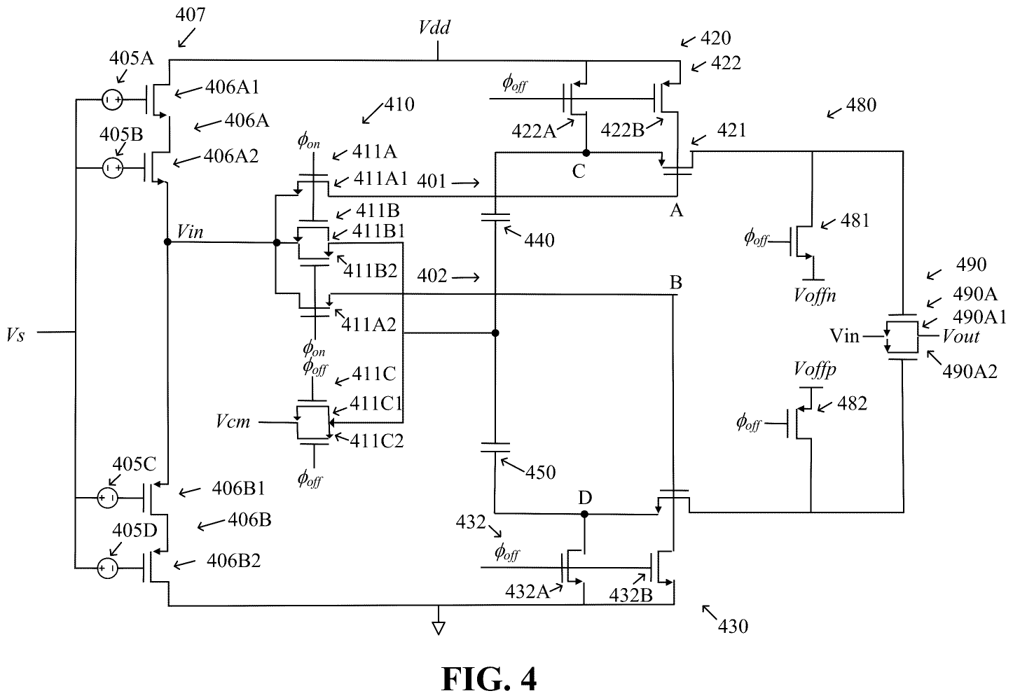

Referring to FIG. 4, an example track and hold (TH) boosted input switches circuit 400 is shown, in accordance with an exemplary aspect.

TH BISC 400 of FIG. 4 differs from TH BISC 200 of FIG. 2 in including a buffer 407 that, in turn, includes four additional transistors 406A1, 406A2, 406B1, 406B2, and power supplies 405A, 405B, 405C, 405D.

FIG. 4 is similar to FIG. 2 but adds a buffer between the source voltage, Vs, and the node Vin. A typical source resistance is 50 ohms and when bandwidth and switching time need to be maximized the low output impedance of 406A2 and 406B1, compared to 50 ohms, provides a much lower drive resistance, by as much as an order of magnitude. Thus the node Vin is isolated from the 50 ohm source resistance by 406A2 and 406B. This can greatly improve switching time and bandwidth. The TH BISC 400 includes a first branch 401 for generating a voltage boosted by some positive voltage above an analog input voltage V_{IN}. The TH BISC 400 includes a second branch 402 for generating a voltage boosted by some negative voltage below an analog input voltage Vin.

The TH BISC 400 includes a supply circuit 405, an input circuit 410, a first switch circuit 420, a second switch circuit 430, a first storage element (hereinafter “bootstrap capacitor”) 440, a second storage element hereinafter “bootstrap capacitor”) 450, a boost turn-off circuit 480, and an output circuit 490.

Input circuit 410 buffers input voltage V_{IN} by presenting a high impedance to a signal source and providing current gain to charge bootstrap capacitors 440 and 450. In the track mode, a switch arrangement [TBD2] is closed and the voltage on the bootstrap capacitors 440 and 450 follow (or track) the input signal V_{IN}. In the hold mode, the switch arrangement [TBD2] is opened, and the bootstrap capacitors 440 and 450 retain the voltage present at the time the bootstrap capacitors 440 and 450 were disconnected from the input circuit 410. The output circuit 490 offers a high impedance to the bootstrap capacitors 440 and 450 to keep the held voltages stored therein from discharging prematurely.

First branch 401 includes elements of input circuit 410, bootstrap capacitor 440, boost turn-off circuit 480, and output circuit 390. First branch 401 includes nodes C and A described further hereinbelow. Second branch 402 includes elements of input circuit 410, bootstrap capacitor 450, boost turn-off circuit 480, and output circuit 490. Second branch 402 includes nodes D and B described further hereinbelow.

### Supply Circuit 405

Supply circuit 405 includes a first supply 405A having a negative terminal connected to a voltage Vs and a positive terminal connected to a gate of a transistor 406A1. Supply circuit 405 includes a second supply 405B having a negative terminal connected to voltage Vs and a positive terminal connected to a gate of a transistor 406A2. Supply circuit 405 includes a third supply 405C having a positive terminal connected to voltage Vs and a negative terminal connected to a gate of a transistor 406B1. Supply circuit 405 includes a fourth supply 405D having a positive terminal connected to voltage Vs and a negative terminal connected to a gate of a transistor 406B2.

A source of transistor 406A1 is connected to a voltage Vdd, a drain of a transistor 422A and a drain of a transistor 422B (of first switch circuit 420). A drain of transistor 406A1 is connected to a source of transistor 406A2. A drain of transistor 406A2 is connected to a drain of a transistor 411A1, a drain of a transistor 411B1, a source of a transistor 411B2, and a source of a transistor 411A2 to form a common node for providing analog input voltage V_{IN}.

### Input Circuit 410

The input circuit 410 includes two complementary switch pairs configured to receive analog input voltage V_{IN}, namely a complementary switch pair 411A and a complementary switch pair 411B. In an aspect as shown, complementary switch pair 411B is disposed between a transistor 411A1 and a transistor 411A2 of complementary switch pair 411A. Complementary switch pair 411A includes transistor 411A1 and transistor 411A2. Complementary switch pair 411B includes a transistor 411B1 and a transistor 411B2.

The input circuit 410 further includes a third complementary switch pair 411C configured to receive a common mode voltage Vcm. Complementary switch pair 411C includes a transistor 411C1 and a transistor 411C2.

Gates of transistor 411A1, transistor 411A2, transistor 411B1, and transistor 411B2, are commonly connected and configured to receive a control signal ∅ₒₙ to turn the transistors 411A1, 411A2, 411B1, and 411B2 all on or all off. Gates of transistor 411C1 and transistor 411C2 are commonly connected and configured to receive a voltage V_{cm} to turn the transistors 4111C1 and 411C2 all on or all off. A source of transistor 411A1 is connected to a node A. A drain of transistor 411A2 is connected to a node B.

### First Switch Circuit 420 and Second Switch Circuit 430

Node A, in addition to being connected to the source of transistor 411A1, is further connected to a gate of transistor 421 and a source of transistor 422B. Node B, in addition to being connected to the drain of transistor 411A2, is further connected to a gate of transistor 431 and a source of transistor 432B.

First switch circuit 420 includes a transistor 421 and complementary switch pair 422. Complementary switch pair 422 includes a transistor 422A and a transistor 422B. A drain of transistor 422A, a drain of transistor 422B are connected to voltage V_{dd}. Gates of transistor 422A and transistor 422B are connected to a control signal ∅_{off}. A source of transistor 422A, a drain of transistor 421, and a first end of bootstrap capacitor 440 form node C.

Second switch circuit 430 includes a transistor 431 and complementary switch pair 432. Complementary switch pair 432 includes a transistor 432A and a transistor 432B. A drain of transistor 432A and a drain of transistor 432B are connected to ground. Gates of transistor 432A and transistor 432B are connected to a control signal ∅_{off}. A source of transistor 432A, a drain of transistor 431, and a first end of bootstrap capacitor 450 form node D.

### Bootstrap Capacitor 440 and Bootstrap Capacitor 450

Bootstrap capacitors 440 and 450 are configured to store a pre-set D.C. boosted voltage (Vboost).

### Boost Turn-off Circuit 480

Boost turn-off circuit 480 includes a transistor 481 and a transistor 482.

Transistor 481 includes a drain connected to a voltage V_{offn}, a source connected to a source of transistor 421 and a gate of a transistor 490A1 of a complementary switch pair 290A of output circuit 490 described in further detail hereinbelow, and a gate connected to a control signal ∅_{off}.

Transistor 482 includes a drain connected to a voltage V_{offn}, a source connected to a source of a transistor 431 and a gate of a transistor 490A2 of a complementary switch pair 490A of output circuit 490 described in further detail hereinbelow, and a gate connected to a control signal ∅_{off}.

### Output Circuit 490

Output circuit 490 includes a complementary switch pair 490A having transistor 490A1 and transistor 490A2. Drains of transistor 490A1 and transistor 490A2 are connected to input voltage V_{IN}. Sources of transistor 490A1 and transistor 490A2 are connected to an output voltage V_{OUT}.

The on resistances of transistor 490A1 and transistor 490A2 are boosted and bootstrapped to be of constant resistance and look like a resistor.

### Circuit Voltages

TH BISC 400 includes various voltage sources including voltage sources Vs, Voffp, Voffn, Vdd, voltage source 405A, voltage source 405B, voltage source 405C, and voltage source 405D.

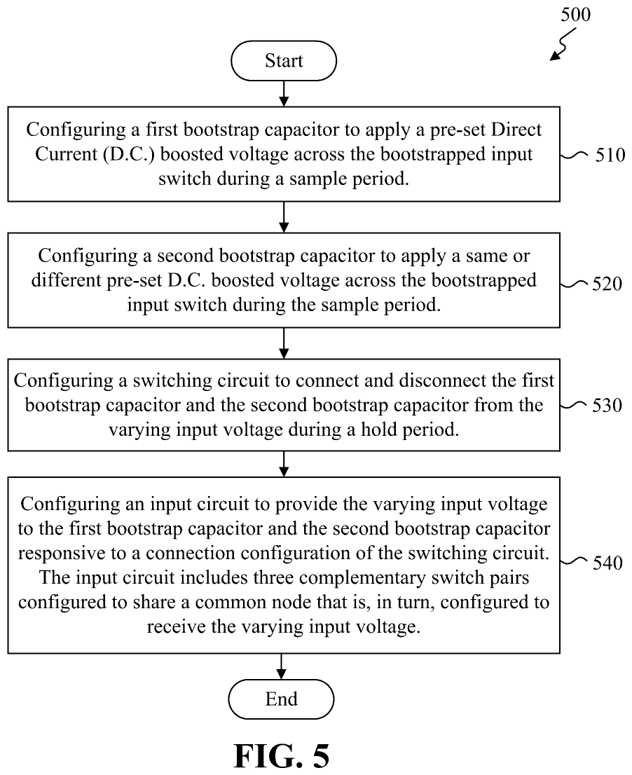

Referring to FIG. 5, an example method 500 for forming a track-and-hold amplifier circuit (hereinafter “circuit”) is shown, in accordance with an exemplary aspect.

At block 510, the method 500 includes configuring a first bootstrap capacitor 140, 240, 340, 440 to apply a pre-set Direct Current (D.C.) boosted voltage across the bootstrapped input switch during a sample period.

At block 520, the method 500 includes configuring a second bootstrap capacitor 150, 250, 350, 450 to apply a same or different pre-set D.C. boosted voltage across the bootstrapped input switch during the sample period.

At block 530, the method 500 includes configuring a switching circuit 120, 130, 220, 230, 320, 330, 420, 430 to connect and disconnect the first bootstrap capacitor 140, 240, 340, 440 and the second bootstrap capacitor 150, 250, 350, 450 from the varying input voltage during a hold period.

At block 540, the method 500 includes configuring an input circuit 110, 210, 310, 410 to provide the varying input voltage to the first bootstrap capacitor 140, 240, 340, 440 and the second bootstrap capacitor 150, 250, 350, 450 responsive to a connection configuration of the switching circuit 120, 130, 220, 230, 320, 330, 420, 430. The input circuit 110, 210, 310, 410 includes three complementary switch pairs (1111A-C), (2111A-B, 212), (311A-C), (411A-C configured to share a common node that is, in turn, configured to receive the varying input voltage Vin.

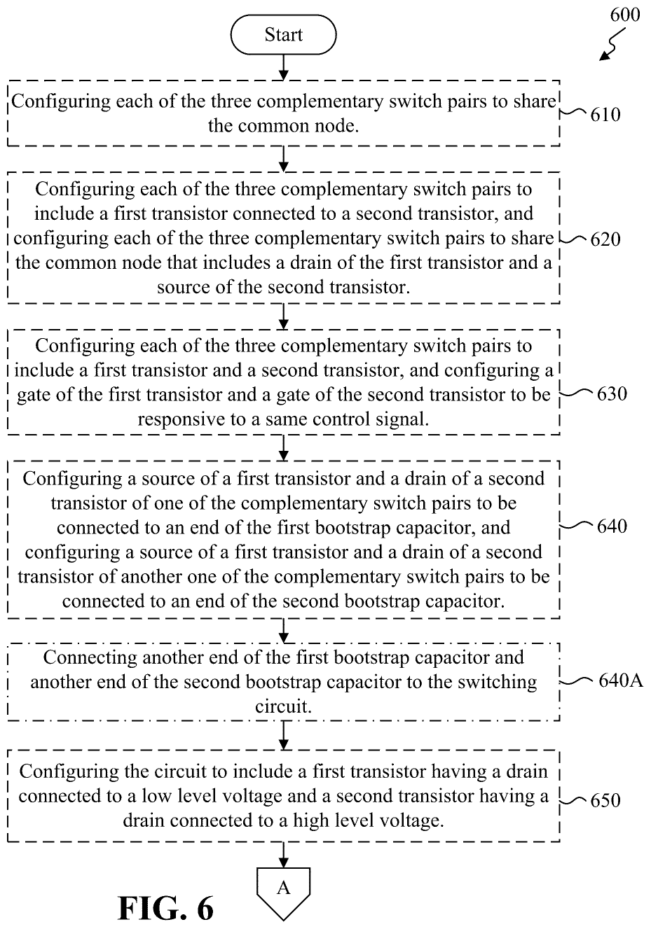

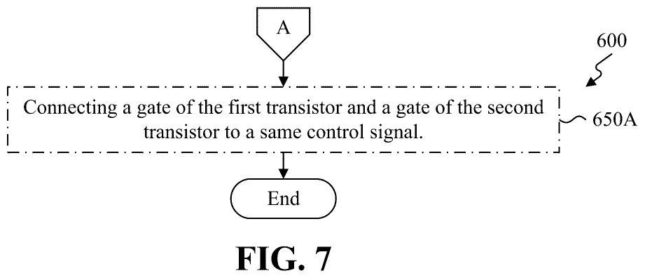

Referring to FIGS. 6-7, an example method 600 corresponding to TH BISC 100 of FIG. 1 and method 500 of FIG. 5 is shown, in accordance with an exemplary aspect.

At block 610, the method 600 includes configuring each of the three complementary switch pairs 1111A-C to share the common node.

At block 620, the method 600 includes configuring each of the three complementary switch pairs 111A-C to include a first transistor 111A1, 111B1, 111C1 connected to a second transistor 111A2, 111B2, 111C2, and configuring each of the three complementary switch pairs 111A-C to share the common node that includes a drain of the first transistor 111A1, 111B1, 111C1 and a source of the second transistor 111A2, 111B2, 111C2.

At block 630, the method 600 includes configuring each of the three complementary switch pairs 111A-C to include a first transistor 111A1, 111B1, 111C1 and a second transistor 111A2, 111B2, 111C2, and configuring a gate of the first transistor 111A1, 111B1, 111C1 and a gate of the second transistor 111A2, 111B2, 111C2 to be responsive to a same control signal ∅ₒₙ.

At block 640, the method 600 includes configuring a source of a first transistor 111A1 and a drain of a second transistor 111A2 of one of the complementary switch pairs 111A to be connected to an end of the first bootstrap capacitor 140, and configuring a source of a first transistor 111C1 and a drain of a second transistor 111C2 of another one of the complementary switch pairs 111C to be connected to an end of the second bootstrap capacitor 150.

In an aspect, block 640 may include block 640A.

At block 640A, the method 600 includes connecting another end of the first bootstrap capacitor 140 and another end of the second bootstrap capacitor 150 to the switching circuit 120, 130.

At block 650, the method 600 includes configuring the circuit to include a first transistor 161 having a drain connected to a low level voltage Vlo_lvl and a second transistor having a drain 171 connected to a high level voltage Vhi_lvl.

In an aspect, block 650 may include block 650A.

At block 650A, the method 600 includes connecting a gate of the first transistor and a gate of the second transistor to a same control signal.

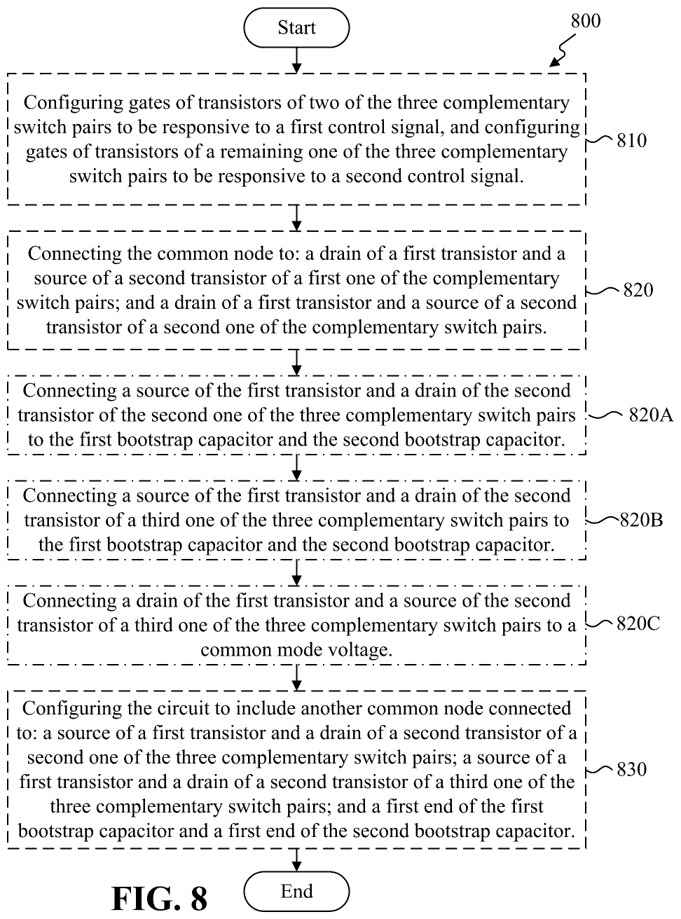

Referring to FIG. 8, an example method 800 corresponding to TH BISC 200 of FIG. 2 and method 500 of FIG. 5 is shown, in accordance with an exemplary aspect.

At block 810, the method 800 includes configuring gates of transistors 211A1, 211B1, 211A1, 211B1 of two 211A, 211B of the three complementary switch pairs 211A-C to be responsive to a first control signal, ∅ₒₙ and configuring gates of transistors of a remaining one 211C of the three complementary switch pairs 211A-C to be responsive to a second control signal ∅_{off}.

At block 820, the method 800 includes connecting the common node to: a drain of a first transistor 211A1 and a source of a second transistor 211A2 of a first one of the complementary switch pairs 211A; and a drain of a first transistor 211B1 and a source of a second transistor 211B2 of a second one 211B of the complementary switch pairs.

In an aspect, block 820 may include one or more of blocks 820A through 820C.

At block 820A, the method 800 includes connecting a source of the first transistor 211B1 and a drain of the second transistor 211B2 of the second one 211B of the three complementary switch pairs 211A-C to the first bootstrap capacitor 240 and the second bootstrap capacitor 250.

At block 820B, the method 800 includes connecting a source of the first transistor 212A and a drain of the second transistor 212B of a third one 212 of the three complementary switch pairs 2111-B, 212 to the first bootstrap capacitor 240 and the second bootstrap capacitor 250.

At block 820C, the method 800 includes connecting a drain of the first transistor 212A and a source of the second transistor 212B of a third one 212 of the three complementary switch pairs 211A-B, 212 to a common mode voltage Vcm.

At block 830, the method 800 includes configuring the circuit 200 to include another common node connected to: a source of a first transistor 211B1 and a drain of a second transistor 211B2 of a second one 211B of the three complementary switch pairs 211A-B, 212; a source of a first transistor 212A and a drain of a second transistor 212B of a third one 212 of the three complementary switch pairs 211A-B, 212; and a first end of the first bootstrap capacitor 240 and a first end of the second bootstrap capacitor 250.

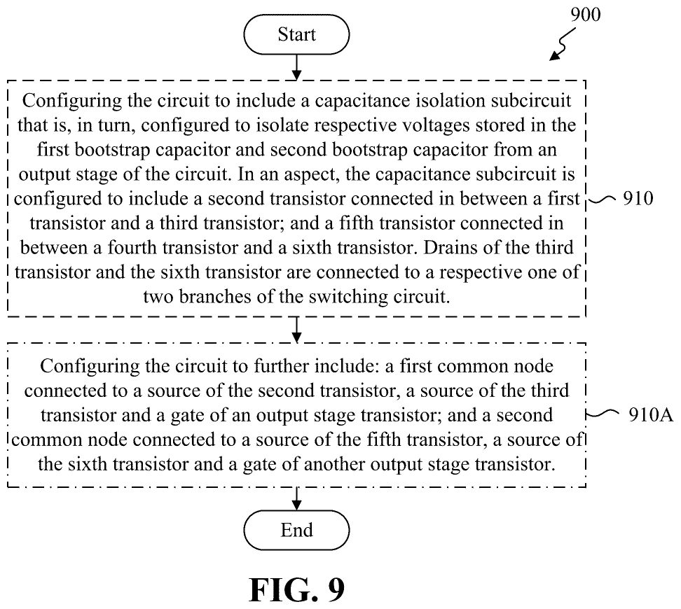

Referring to FIG. 9, an example method 900 corresponding to TH BISC 300 of FIG. 3 and method 500 of FIG. 5 is shown, in accordance with an exemplary aspect.

At block 910, the method 900 includes configuring the circuit 300 to include a capacitance isolation subcircuit that is, in turn, configured to isolate respective voltages stored in the first bootstrap capacitor 340 and second bootstrap capacitor 350 from an output stage 390 of the circuit 300. In an aspect, the capacitance subcircuit is configured to include a second transistor 383A connected in between a first transistor 381 and a third transistor 383B; and a fifth transistor 384A connected in between a fourth transistor 382 and a sixth transistor 384B. Drains of the third transistor 383B and the sixth transistor 384B are connected to a respective one of two branches 320, 330 of the switching circuit.

In an aspect, block 910 may include one or more of block 910A.

At block 910A, the method 900 includes configuring the circuit to further include: a first common node connected to a source of the second transistor, a source of the third transistor and a gate of an output stage transistor; and a second common node connected to a source of the fifth transistor, a source of the sixth transistor and a gate of another output stage transistor.

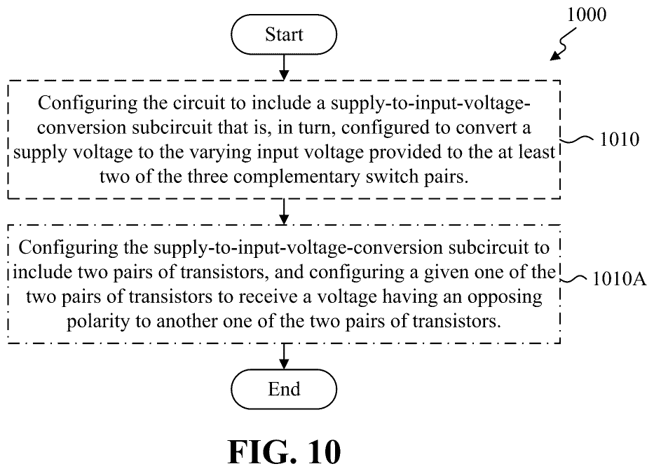

Referring to FIG. 10, an example method 1000 corresponding to TH BISC 400 of FIG. 4 and method 500 of FIG. 5 is shown, in accordance with an exemplary aspect.

At block 1010, the method 1000 includes configuring the circuit 400 to include a supply-to-input-voltage-conversion subcircuit 407 that is, in turn, configured to convert a supply voltage Vs to the varying input voltage Vin provided to the at least two 411A-B of the three complementary switch pairs 411A-C.

In an aspect, block 1010 may include block 1010A.

At block 1010A, the method 1000 includes configuring the supply-to-input-voltage-conversion subcircuit 407 to include two pairs of transistors 406A, 406B, and configuring a given one 406A of the two pairs of transistors 406A, 406B to receive a voltage having an opposing polarity to another one 406B of the two pairs of transistors 406A, 406B.

In an aspect, block 1010A may include block 1010A1.

At block 1010A1, the method 1000 includes configuring the given one 406A of the two pairs of transistors 406A, 406B to be open when the other one 406B of the two pairs of transistors 406A, 406B is configured to be closed, and configuring the given one 406A of the two pairs of transistors 406A, 406B to be closed when the other one 406B of the two pairs of transistors 406A, 406B is configured to be open.

Clause 1. A circuit, comprising: a first bootstrap capacitor configured to apply a pre-set Direct Current (DC) voltage across the bootstrapped input switch during a sample period; a second bootstrap capacitor configured to apply a same or different pre-set DC voltage across the bootstrapped input switch during the sample period; a switching circuit configured to connect and disconnect the first bootstrap capacitor and the second bootstrap capacitor from the varying input voltage during a hold period; and an input circuit configured to provide the varying input voltage to the first bootstrap capacitor and the second bootstrap capacitor responsive to a connection configuration of the switching circuit, the input circuit comprising three complementary switch pairs configured to share a common node that is, in turn, configured to receive the varying input voltage.

Clause 2. The circuit in accordance with clause 1, wherein each of the three complementary switch pairs share the common node configured to receive the varying input voltage.

Clause 3. The circuit in accordance with any preceding clauses, wherein each of the three complementary switch pairs comprise a first transistor connected to a second transistor, and wherein each of the three complementary switch pairs share the common node that includes a drain of the first transistor and a source of the second transistor.

Clause 4. The circuit in accordance with any preceding clauses, wherein each of the three complementary switch pairs comprise a first transistor and a second transistor, and wherein a gate of the first transistor and a gate of the second transistor are configured to be responsive to a same control signal.

Clause 5. The circuit in accordance with any preceding clauses, wherein a source of a first transistor and a drain of a second transistor of one of the complementary switch pairs are connected to an end of the first bootstrap capacitor, and wherein a source of a first transistor and a drain of a second transistor of another one of the complementary switch pairs are connected to an end of the second bootstrap capacitor.

Clause 6. The circuit in accordance with any preceding clauses, wherein another end of the first bootstrap capacitor and another end of the second bootstrap capacitor are connected to the switching circuit.

Clause 7. The circuit in accordance with any preceding clauses, further comprising a first transistor having a drain connected to a low level voltage and a second transistor having a drain connected to a high level voltage.

Clause 8. The circuit in accordance with any preceding clauses, wherein a gate of the first transistor and a gate of the second transistor are connected to a same control signal.

Clause 9. The circuit in accordance with any preceding clauses, wherein gates of transistors of two of the three complementary switch pairs are configured to be responsive to a first control signal, and wherein gates of transistors of a remaining one of the three complementary switch pairs are configured to be responsive to a second control signal.

Clause 10. The circuit in accordance with any preceding clauses, wherein the common node is connected to: a drain of a first transistor and a source of a second transistor of a first one of the complementary switch pairs; a drain of a first transistor and a source of a second transistor of a second one of the complementary switch pairs.

Clause 11. The circuit in accordance with any preceding clauses, wherein a source of the first transistor and a drain of the second transistor of the second one of the three complementary switch pairs are connected to the first bootstrap capacitor and the second bootstrap capacitor.

Clause 12. The circuit in accordance with any preceding clauses, wherein a source of the first transistor and a drain of the second transistor of a third one of the three complementary switch pairs are connected to the first bootstrap capacitor and the second bootstrap capacitor.

Clause 13. The circuit in accordance with any preceding clauses, wherein a drain of the first transistor and a source of the second transistor of a third one of the three complementary switch pairs are connected to a common mode voltage.

Clause 14. The circuit in accordance with any preceding clauses, further comprising another common node connected to: a source of a first transistor and a drain of a second transistor of a second one of the three complementary switch pairs; a source of a first transistor and a drain of a second transistor of a third one of the three complementary switch pairs; and a first end of the first bootstrap capacitor and a first end of the second bootstrap capacitor.

Clause 15. The circuit in accordance with any preceding clauses, further comprising a capacitance isolation subcircuit configured to isolate respective voltages stored in the first bootstrap capacitor and second bootstrap capacitor from an output stage of the circuit, the capacitance subcircuit comprising: a second transistor connected in between a first transistor and a third transistor; and a fifth transistor connected in between a fourth transistor and a sixth transistor, wherein drains of the third transistor and the sixth transistor are connected to a respective one of two branches of the switching circuit.

Clause 16. The circuit in accordance with any preceding clauses, further comprising: a first common node connected to a source of the second transistor, a source of the third transistor and a gate of an output stage transistor; and a second common node connected to a source of the fifth transistor, a source of the sixth transistor and a gate of another output stage transistor.

Clause 17. The circuit in accordance with clause 1, further comprising a supply-to-input-voltage-conversion subcircuit configured to convert a supply voltage to the varying input voltage provided to the at least two of the three complementary switch pairs.

Clause 18. The circuit in accordance with any preceding clauses, wherein the supply-to-input-voltage-conversion subcircuit comprises two pairs of transistors, and wherein a given one of the two pairs of transistors is configured to receive a voltage having an opposing polarity to another one of the two pairs of transistors.

Clause 19. The circuit in accordance with any preceding clauses, wherein the given one of the two pairs of transistors is configured to be open when the other one of the two pairs of transistors is configured to be closed, and wherein the given one of the two pairs of transistors is configured to be closed when the other one of the two pairs of transistors is configured to be open.

Clause 20. A method, comprising: configuring a first bootstrap capacitor to sample a varying input voltage during a first sample period; configuring a second bootstrap capacitor to sample the varying input voltage during a second sample period; configuring a switching circuit to connect and disconnect the first bootstrap capacitor and the second bootstrap capacitor from the varying input voltage during at least one hold period; and configuring an input circuit to provide the varying input voltage to the first bootstrap capacitor and the second bootstrap capacitor responsive to a connection configuration of the switching circuit, the input circuit comprising three complementary switch pairs, at least two of the three complementary switch pairs being configured to share a common node that is, in turn, configured to receive the varying input voltage.

Clause 21. The method in accordance with clause 20, wherein each of the three complementary switch pairs share the common node configured to receive the varying input voltage.

Clause 22. The method in accordance with any preceding clauses, wherein each of the three complementary switch pairs comprise a first transistor connected to a second transistor, and wherein each of the three complementary switch pairs share the common node that includes a drain of the first transistor and a source of the second transistor.

Clause 23. The method in accordance with any preceding clauses, wherein a source of a first transistor and a drain of a second transistor of one of the complementary switch pairs are connected to an end of the first bootstrap capacitor, and wherein a source of a first transistor and a drain of a second transistor of another one of the complementary switch pairs are connected to an end of the second bootstrap capacitor.

Clause 24. The method in accordance with any preceding clauses, wherein another end of the first bootstrap capacitor and another end of the second bootstrap capacitor are connected to the switching circuit.

Clause 25. The method in accordance with any preceding clauses, wherein gates of transistors of two of the three complementary switch pairs are configured to be responsive to a first control signal, and wherein gates of transistors of a remaining one of the three complementary switch pairs are configured to be responsive to a second control signal.

Clause 26. The method in accordance with any preceding clauses, wherein the common node is connected to: a drain of a first transistor and a source of a second transistor of a first one of the complementary switch pairs; a drain of a first transistor and a source of a second transistor of a second one of the complementary switch pairs.

Clause 27. The method in accordance with any preceding clauses, further comprising a capacitance isolation subcircuit configured to isolate respective voltages stored in the first bootstrap capacitor and second bootstrap capacitor from an output stage of the circuit, the capacitance subcircuit comprising: a second transistor connected in between a first transistor and a third transistor; and a fifth transistor connected in between a fourth transistor and a sixth transistor, wherein drains of the third transistor and the sixth transistor are connected to a respective one of two branches of the switching circuit.

Clause 28. The method in accordance with any preceding clauses, further comprising: a first common node connected to a source of the second transistor, a source of the third transistor and a gate of an output stage transistor; and a second common node connected to a source of the fifth transistor, a source of the sixth transistor and a gate of another output stage transistor.

Clause 29. The method in accordance with any preceding clauses, further comprising a supply-to-input-voltage-conversion subcircuit configured to convert a supply voltage to the varying input voltage provided to the at least two of the three complementary switch pairs.

Various aspects of the disclosure may take the form of an entirely or partially hardware aspect, an entirely or partially software aspect, or a combination of software and hardware. Furthermore, as described herein, various aspects of the disclosure (e.g., systems and methods) may take the form of a computer program product comprising a computer-readable non-transitory storage medium having computer-accessible instructions (e.g., computer-readable and/or computer-executable instructions) such as computer software, encoded or otherwise embodied in such storage medium. Those instructions can be read or otherwise accessed and executed by one or more processors to perform or permit the performance of the operations described herein. The instructions can be provided in any suitable form, such as source code, compiled code, interpreted code, executable code, static code, dynamic code, assembler code, combinations of the foregoing, and the like. Any suitable computer-readable non-transitory storage medium may be utilized to form the computer program product. For instance, the computer-readable medium may include any tangible non-transitory medium for storing information in a form readable or otherwise accessible by one or more computers or processor(s) functionally coupled thereto. Non-transitory storage media can include read-only memory (ROM); random access memory (RAM); magnetic disk storage media; optical storage media; flash memory, and so forth.

Aspects of this disclosure are described herein with reference to block diagrams and flowchart illustrations of methods, systems, apparatuses, and computer program products. It can be understood that each block of the block diagrams and flowchart illustrations, and combinations of blocks in the block diagrams and flowchart illustrations, respectively, can be implemented by computer-accessible instructions. In certain implementations, the computer-accessible instructions may be loaded or otherwise incorporated into a general-purpose computer, a special-purpose computer, or another programmable information processing apparatus to produce a particular machine, such that the operations or functions specified in the flowchart block or blocks can be implemented in response to execution at the computer or processing apparatus.

Unless otherwise expressly stated, it is in no way intended that any device protocol, procedure, process, or method set forth herein be construed as requiring that its acts or steps be performed in a specific order. Accordingly, where a process or method claim does not actually recite an order to be followed by its acts or steps, or it is not otherwise specifically recited in the claims or descriptions of the subject disclosure that the steps are to be limited to a specific order, it is in no way intended that an order be inferred, in any respect. This holds for any possible non-express basis for interpretation, including: matters of logic with respect to the arrangement of steps or operational flow; plain meaning derived from grammatical organization or punctuation; the number or type of aspects described in the specification or annexed drawings; or the like.

As used in this disclosure, including the annexed drawings, the terms “component,” “module,” “system,” and the like are intended to refer to a computer-related entity or an entity related to an apparatus with one or more specific functionalities. The entity can be either hardware, a combination of hardware and software, software, or software in execution. One or more of such entities are also referred to as “functional elements.” As an example, a component can be a process running on a processor, a processor, an object, an executable, a thread of execution, a program, and/or a computer. For example, both an application running on a server or network controller, and the server or network controller can be a component. One or more components can reside within a process and/or thread of execution and a component can be localized on one computer and/or distributed between two or more computers. Also, these components can execute from various computer readable media having various data structures stored thereon. The components can communicate via local and/or remote processes such as in accordance with a signal having one or more data packets (e.g., data from one component interacting with another component in a local system, distributed system, and/or across a network such as the Internet with other systems via the signal). As another example, a component can be an apparatus with specific functionality provided by mechanical parts operated by electric or electronic circuitry, which parts can be controlled or otherwise operated by program code executed by a processor. As yet another example, a component can be an apparatus that provides specific functionality through electronic components without mechanical parts, the electronic components can include a processor to execute program code that provides, at least partially, the functionality of the electronic components. As still another example, interface(s) can include I/O components or Application Programming Interface (API) components. While the foregoing examples are directed to aspects of a component, the exemplified aspects or features also apply to a system, module, and similar.

In addition, the term “or” is intended to mean an inclusive “or” rather than an exclusive “or.” That is, unless specified otherwise, or clear from context, “X employs A or B” is intended to mean any of the natural inclusive permutations. That is, if X employs A; X employs B; or X employs both A and B, then “X employs A or B” is satisfied under any of the foregoing instances. Moreover, articles “a” and “an” as used in this specification and annexed drawings should be construed to mean “one or more” unless specified otherwise or clear from context to be directed to a singular form.

In addition, the terms “example” and “such as” and “e.g.” are utilized herein to mean serving as an instance or illustration. Any aspect or design described herein as an “example” or referred to in connection with a “such as” clause or “e.g.” is not necessarily to be construed as preferred or advantageous over other aspects or designs described herein. Rather, use of the terms “example” or “such as” or “e.g.” is intended to present concepts in a concrete fashion. The terms “first,” “second,” “third,” and so forth, as used in the claims and description, unless otherwise clear by context, is for clarity only and does not necessarily indicate or imply any order in time or space.

The term “processor,” as utilized in this disclosure, can refer to any computing processing unit or device comprising processing circuitry that can operate on data and/or signaling. A computing processing unit or device can include, for example, single-core processors; single-processors with software multithread execution capability; multi-core processors; multi-core processors with software multithread execution capability; multi-core processors with hardware multithread technology; parallel platforms; and parallel platforms with distributed shared memory. Additionally, a processor can include an integrated circuit, an application specific integrated circuit (ASIC), a digital signal processor (DSP), a field programmable gate array (FPGA), a programmable logic controller (PLC), a complex programmable logic device (CPLD), a discrete gate or transistor logic, discrete hardware components, or any combination thereof designed to perform the functions described herein. In some cases, processors can exploit nano-scale architectures, such as molecular and quantum-dot based transistors, switches and gates, in order to optimize space usage or enhance performance of user equipment. A processor may also be implemented as a combination of computing processing units.

In addition, terms such as “store,” “data store,” data storage,” “database,” and substantially any other information storage component relevant to operation and functionality of a component, refer to “memory components,” or entities embodied in a “memory” or components comprising the memory. It will be appreciated that the memory components described herein can be either volatile memory or nonvolatile memory, or can include both volatile and nonvolatile memory. Moreover, a memory component can be removable or affixed to a functional element (e.g., device, server).

Simply as an illustration, nonvolatile memory can include read only memory (ROM), programmable ROM (PROM), electrically programmable ROM (EPROM), electrically erasable ROM (EEPROM), or flash memory. Volatile memory can include random access memory (RAM), which acts as external cache memory. By way of illustration and not limitation, RAM is available in many forms such as synchronous RAM (SRAM), dynamic RAM (DRAM), synchronous DRAM (SDRAM), double data rate SDRAM (DDR SDRAM), enhanced SDRAM (ESDRAM), Synchlink DRAM (SLDRAM), and direct Rambus RAM (DRRAM). Additionally, the disclosed memory components of systems or methods herein are intended to comprise, without being limited to comprising, these and any other suitable types of memory.

Various aspects described herein can be implemented as a method, apparatus, or article of manufacture using special programming as described herein. In addition, various of the aspects disclosed herein also can be implemented by means of program modules or other types of computer program instructions specially configured as described herein and stored in a memory device and executed individually or in combination by one or more processors, or other combination of hardware and software, or hardware and firmware. Such specially configured program modules or computer program instructions, as described herein, can be loaded onto a general-purpose computer, a special-purpose computer, or another type of programmable data processing apparatus to produce a machine, such that the instructions which execute on the computer or other programmable data processing apparatus create a means for implementing the functionality of disclosed herein.

The term “article of manufacture” as used herein is intended to encompass a computer program accessible from any non-transitory computer-readable device, carrier, or media. For example, computer readable media can include but are not limited to magnetic storage devices (e.g., hard drive disk, floppy disk, magnetic strips, or similar), optical discs (e.g., compact disc (CD), digital versatile disc (DVD), blu-ray disc (BD), or similar), smart cards, and flash memory devices (e.g., card, stick, key drive, or similar).

The detailed description set forth herein in connection with the annexed figures is intended as a description of various configurations or implementations and is not intended to represent the only configurations or implementations in which the concepts described herein may be practiced. The detailed description includes specific details for the purpose of providing a thorough understanding of various concepts. However, it will be apparent to those skilled in the art that these concepts may be practiced without these specific details or with variations of these specific details. In some instances, well-known components are shown in block diagram form, while some blocks may be representative of one or more well-known components.

The previous description of the disclosure is provided to enable a person skilled in the art to make or use the disclosure. Various modifications to the disclosure will be readily apparent to those skilled in the art, and the common principles defined herein may be applied to other variations without departing from the scope of the disclosure. Furthermore, although elements of the described aspects may be described or claimed in the singular, the plural is contemplated unless limitation to the singular is explicitly stated. Additionally, all or a portion of any aspect may be utilized with all or a portion of any other aspect, unless stated otherwise. Thus, the disclosure is not to be limited to the examples and designs described herein but is to be accorded the widest scope consistent with the principles and novel features disclosed herein.

What is claimed is:

1. A circuit, comprising:
a first bootstrap capacitor configured to apply a pre-set Direct Current (DC) voltage across the bootstrapped input switch during a sample period;
a second bootstrap capacitor configured to apply a same or different pre-set DC voltage across the bootstrapped input switch during the sample period;
a switching circuit configured to connect and disconnect the first bootstrap capacitor and the second bootstrap capacitor from the varying input voltage during a hold period; and
an input circuit configured to provide the varying input voltage to the first bootstrap capacitor and the second bootstrap capacitor responsive to a connection configuration of the switching circuit, the input circuit comprising three complementary switch pairs being configured to share a common node that is, in turn, configured to receive the varying input voltage.

2. The circuit in accordance with claim 1, wherein each of the three complementary switch pairs share the common node configured to receive the varying input voltage.

3. The circuit in accordance with claim 1, wherein each of the three complimentary switch pairs comprise a first transistor connected to a second transistor, and wherein each of the three complementary switch pairs share the common node that includes a drain of the first transistor and a source of the second transistor.

4. The circuit in accordance with claim 1, wherein each of the three complementary switch pairs comprise a first transistor and a second transistor, and wherein a gate of the first transistor and a gate of the second transistor are configured to be responsive to a same control signal.

5. The circuit in accordance with claim 1, wherein a source of a first transistor and a drain of a second transistor of one of the complementary switch pairs are connected to an end of the first bootstrap capacitor, and wherein a source of a first transistor and a drain of a second transistor of another one of the complementary switch pairs are connected to an end of the second bootstrap capacitor.

6. The circuit in accordance with claim 5, wherein another end of the first bootstrap capacitor and another end of the second bootstrap capacitor are connected to the switching circuit.

7. The circuit in accordance with claim 1, further comprising a first transistor having a drain connected to a low level voltage and a second transistor having a drain connected to a high level voltage.

8. The circuit in accordance with claim 6, wherein a gate of the first transistor and a gate of the second transistor are connected to a same control signal.

9. The circuit in accordance with claim 1, wherein gates of transistors of two of the three complementary switch pairs are configured to be responsive to a first control signal, and wherein gates of transistors of a remaining one of the three complementary switch pairs are configured to be responsive to a second control signal.

10. The circuit in accordance with claim 1, wherein the common node is connected to:
a drain of a first transistor and a source of a second transistor of a first one of the complementary switch pairs;
a drain of a first transistor and a source of a second transistor of a second one of the complementary switch pairs.

11. The circuit in accordance with claim 10, wherein a source of the first transistor and a drain of the second transistor of the second one of the three complementary switch pairs are connected to the first bootstrap capacitor and the second bootstrap capacitor.

12. The circuit in accordance with claim 10, wherein a source of the first transistor and a drain of the second transistor of a third one of the three complementary switch pairs are connected to the first bootstrap capacitor and the second bootstrap capacitor.

13. The circuit in accordance with claim 10, wherein a drain of the first transistor and a source of the second transistor of a third one of the three complementary switch pairs are connected to a common mode voltage.

14. The circuit in accordance with claim 1, further comprising another common node connected to:
a source of a first transistor and a drain of a second transistor of a second one of the three complementary switch pairs;
a source of a first transistor and a drain of a second transistor of a third one of the three complementary switch pairs; and
a first end of the first bootstrap capacitor and a first end of the second bootstrap capacitor.

15. The circuit in accordance with claim 1, further comprising a capacitance isolation subcircuit configured to isolate respective voltages stored in the first bootstrap capacitor and second bootstrap capacitor from an output stage of the circuit, the capacitance subcircuit comprising:
a second transistor connected in between a first transistor and a third transistor; and
a fifth transistor connected in between a fourth transistor and a sixth transistor,
wherein drains of the third transistor and the sixth transistor are connected to a respective one of two branches of the switching circuit.

16. The circuit in accordance with claim 15, further comprising:
a first common node connected to a source of the second transistor, a source of the third transistor and a gate of an output stage transistor; and
a second common node connected to a source of the fifth transistor, a source of the sixth transistor and a gate of another output stage transistor.

17. The circuit in accordance with claim 1, further comprising a supply-to-input-voltage-conversion subcircuit configured to convert a supply voltage to the varying input voltage provided to the at least two of the three complementary switch pairs.

18. The circuit in accordance with claim 17, wherein the supply-to-input-voltage-conversion subcircuit comprises two pairs of transistors, and wherein a given one of the two pairs of transistors is configured to receive a voltage having an opposing polarity to another one of the two pairs of transistors.

19. The circuit in accordance with claim 18, wherein the given one of the two pairs of transistors is configured to be open when the other one of the two pairs of transistors is configured to be closed, and wherein the given one of the two pairs of transistors is configured to be closed when the other one of the two pairs of transistors is configured to be open.

20. A method, comprising:
configuring a first bootstrap capacitor to sample a varying input voltage during a first sample period;
configuring a second bootstrap capacitor to sample the varying input voltage during a second sample period;
configuring a switching circuit to connect and disconnect the first bootstrap capacitor and the second bootstrap capacitor from the varying input voltage during at least one hold period; and
configuring an input circuit to provide the varying input voltage to the first bootstrap capacitor and the second bootstrap capacitor responsive to a connection configuration of the switching circuit, the input circuit comprising three complementary switch pairs, at least two of the three complementary switch pairs being configured to share a common node that is, in turn, configured to receive the varying input voltage.

21. The method in accordance with claim 20, wherein each of the three complementary switch pairs share the common node configured to receive the varying input voltage.

22. The method in accordance with claim 20, wherein each of the three complementary switch pairs comprise a first transistor connected to a second transistor, and wherein each of the three complementary switch pairs share the common node that includes a drain of the first transistor and a source of the second transistor.

23. The method in accordance with claim 20, wherein a source of a first transistor and a drain of a second transistor of one of the complementary switch pairs are connected to an end of the first bootstrap capacitor, and wherein a source of a first transistor and a drain of a second transistor of another one of the complementary switch pairs are connected to an end of the second bootstrap capacitor.

24. The method in accordance with claim 23, wherein another end of the first bootstrap capacitor and another end of the second bootstrap capacitor are connected to the switching circuit.

25. The method in accordance with claim 20, wherein gates of transistors of two of the three complementary switch pairs are configured to be responsive to a first control signal, and wherein gates of transistors of a remaining one of the three complementary switch pairs are configured to be responsive to a second control signal.

26. The method in accordance with claim 20, wherein the common node is connected to:
a drain of a first transistor and a source of a second transistor of a first one of the complementary switch pairs;
a drain of a first transistor and a source of a second transistor of a second one of the complementary switch pairs.

27. The method in accordance with claim 20, further comprising a capacitance isolation subcircuit configured to isolate respective voltages stored in the first bootstrap capacitor and second bootstrap capacitor from an output stage of the circuit, the capacitance subcircuit comprising:
a second transistor connected in between a first transistor and a third transistor; and
a fifth transistor connected in between a fourth transistor and a sixth transistor,
wherein drains of the third transistor and the sixth transistor are connected to a respective one of two branches of the switching circuit.

28. The method in accordance with claim 27, further comprising:
a first common node connected to a source of the second transistor, a source of the third transistor and a gate of an output stage transistor; and
a second common node connected to a source of the fifth transistor, a source of the sixth transistor and a gate of another output stage transistor.

29. The method in accordance with claim 20, further comprising a supply-to-input-voltage-conversion subcircuit configured to convert a supply voltage to the varying input voltage provided to the at least two of the three complementary switch pairs.
